(19) United States
(12) Patent Application Publication
(10) Pub. No.: US 2009/0294064 A1
(43) Pub. Date: Dec. 3, 2009

(54) FOCUS RING AND PLASMA PROCESSING APPARATUS

(75) Inventor: Nobuyuki NAGAYAMA, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/473,707

(22) Filed: May 28, 2009

Related U.S. Application Data
(60) Provisional application No. 61/088,745, filed on Aug. 14, 2008.

(30) Foreign Application Priority Data
May 30, 2008 (JP) 2008-142806

(51) Int. Cl. H01L 21/3065

(52) U.S. Cl. 156/345.39

(57) ABSTRACT

A focus ring that can eliminate the gap between a mounting stage and the focus ring in a plasma processing apparatus to prevent damage to a side wall of the mounting stage of a plasma processing apparatus and attachment of particles to a substrate to be processed resulting from spread of plasma. The focus ring has an annular shape and is provided in an outer peripheral edge portion of an upper surface of the mounting stage. The focus ring is comprised of a combination of a plurality of focus ring pieces formed by dividing the focus ring in a circumferential direction of the annular shape, and an annular band member that urges each of the focus ring pieces toward a center of the focus ring.

### BACKGROUND OF THE INVENTION

1. Field of the Invention

The present invention relates to a focus ring and a plasma processing apparatus, and in particular to a focus ring that used in a processing chamber in which a substrate such as a semiconductor wafer is subjected to predetermined plasma processing such as etching processing and that is disposed such as to surround the substrate, and a plasma processing apparatus having the focus ring.

2. Description of the Related Art

Plasma processing apparatuses including etching processing apparatuses are configured such that a substrate to be processed, for example, a semiconductor wafer is mounted on a mounting stage in a processing chamber of which interior can be airtightly sealed, plasma is produced in the processing chamber, and the substrate to be processed is subjected to plasma processing by causing the produced plasma to act on the substrate to be processed.

Generally, in such a plasma processing apparatus, an annular focus ring is disposed such as to surround an outer peripheral edge portion of an upper surface of the mounting stage and an outer peripheral portion of the substrate to be processed so as to alleviate discontinuity due to an edge face effect of an over-surface bias voltage on the substrate to be processed and ensure uniform processing in a central portion and a peripheral edge portion of the substrate to be processed.

Examples of publications disclosing prior arts related to a focus ring or a plasma processing apparatus having the focus ring include Japanese Laid-open Patent Publication (Kokai) No. 2005-277369.

Japanese Laid-open Patent Publication (Kokai) No. 2005-277369 describes a focus ring that is comprised of a ring-shaped lower member made of a dielectric material, and a ring-shaped upper member that is disposed on the lower member and made of a conductive material, and constructed such that an outer peripheral side (outer peripheral portion) of an upper surface of the upper member is formed as a flat portion at a higher level than a surface to be processed of a substrate to be processed, and an inner peripheral portion of this flat portion is inclined so that the outer peripheral portion can be at a higher level than the inner peripheral portion. According to this focus ring, an electric field effect can be exerted by, for example, making constituent materials of the upper and lower members different, or inserting a member for adjusting impedance, and as a result, spread of plasma to a side wall of an electrostatic chuck (ESC) as a mounting stage and a rear surface of the substrate to be processed can be reduced.

However, the focus ring and the electrostatic chuck heated during plasma processing thermally expand and change in outer diameter or inner diameter. In the case that their outer diameter or inner diameter changes, the focus ring and the electrostatic chuck come into abutment with each other, and if the thermal expansion further continues, the focus ring and so on are internally-stressed due to a temperature change, and as a result, damage such as cracking may occur. Accordingly, with consideration given to a difference in thermal expansion, the focus ring and the electrostatic chuck are designed such that the inner diameter of the focus ring allows for a larger margin to some extent than the outer diameter of the electrostatic chuck, and hence a predetermined gap exists between the focus ring and the electrostatic chuck.

That is, in the above described prior art as well, because a predetermined gap is provided between the focus ring and the electrostatic chuck, and plasma spreads into the gap, the side wall of the electrostatic chuck becomes damaged, or a problem of particle attachment arises, i.e. deposit of organic matter becomes attached to a rear surface of the substrate to be processed due to the spreading plasma.

### SUMMARY OF THE INVENTION

The present invention provides a focus ring that can eliminate the gap between a mounting stage and the focus ring to prevent damage to a side wall of the mounting stage and attachment of particles to a substrate to be processed resulting from spread of plasma, and a plasma processing apparatus having the focus ring.

Accordingly, in a first aspect of the present invention, there is provided a focus ring with an annular shape that is provided in an outer peripheral edge portion of an upper surface of a mounting stage of a plasma processing apparatus having an accommodating chamber in which a substrate is accommodated and subjected to plasma processing, and the mounting stage that is disposed in the accommodating chamber and on which the substrate is mounted, comprising a combination of a plurality of focus ring pieces formed by dividing the focus ring in a circumferential direction of the annular shape, and an annular band member that urges each of the focus ring pieces toward a center of the focus ring.

According to the first aspect of the present invention, because the focus ring is comprised of a combination of a plurality of focus ring pieces formed by dividing the focus ring in the circumferential direction, and the annular band member that urges each of the focus ring pieces toward the center of the focus ring, an internal stress of the focus ring arising from a change in the temperature thereof can be diffused to prevent damage such as cracking, and the focus ring can change its inner diameter in response to expansion or contraction of the mounting stage arising from a temperature change. As a result, the gap between a side wall of the mounting stage and an inner peripheral surface of the focus ring can be eliminated, and spread of plasma and damage to the side wall of the mounting stage, attachment of particles to the substrate to be processed, and so on resulting from the spread of plasma can be prevented.

The first aspect of the present invention can provide a focus ring, wherein abutting portions of focus ring pieces in the combination form joint structures that vertically overlap each other.

According to the first aspect of the present invention, because the abutting portions of the focus ring pieces in the combination form joint structures that vertically overlap each other, plasma moving vertically can be prevented from spreading to the interior of the focus ring through the gap between the abutting portions of the focus ring pieces.

The first aspect of the present invention can provide a focus ring, wherein the focus ring comprises a combination of focus ring pieces formed by dividing the focus ring into two, three, or four in the circumferential direction of the annular shape.

According to the first aspect of the present invention, because the focus ring is comprised of a combination of focus ring pieces formed by dividing the focus ring into two, three, or four in the circumferential direction of the annular shape, cracking and so on caused by an internal stress can be prevented without bringing about an increase in the number of components, and moreover, because the focus ring pieces having the same shape can be used, productivity, the ease of assembly, and so on can be increased.

The first aspect of the present invention can provide a focus ring, wherein the annular band member is made of resin or rubber.

According to the first aspect of the present invention, because the annular band member is made of resin or rubber, an urging force toward the center of the focus ring can be easily added to each focus ring piece using the elasticity of the annular band member.

The first aspect of the present invention can provide a focus ring, wherein the annular band member is disposed in a trench portion or a cut portion formed in an outer peripheral portion of the focus ring, and is blocked from exposure of plasma.

According to the first aspect of the present invention, because the annular band member is disposed in a trench portion or a cut portion formed in the outer peripheral portion of the focus ring, and is blocked from exposure of plasma, the annular band member can be prevented from becoming worn, damaged, and so on due to exposure to plasma.

The first aspect of the present invention can provide a focus ring, wherein the annular band member is an O-ring.

According to the first aspect of the present invention, because the annular band member is an O-ring, a sufficient urging force can be obtained by a simple constructional member, and the ease of assembly can be increased.

Accordingly, in a second aspect of the present invention, there is provided a plasma processing apparatus having an accommodating chamber in which a substrate is accommodated and subjected to plasma processing, and a mounting stage that is disposed in the accommodating chamber and on which the substrate is mounted, comprising a focus ring with an annular shape that is provided in an outer peripheral edge portion of an upper surface of the mounting stage, wherein the focus ring comprises a combination of a plurality of focus ring pieces formed by dividing the focus ring in a circumferential direction of the annular shape, and an annular band member that urges each of the focus ring pieces toward a center of the focus ring.

According to the second aspect of the present invention, because the focus ring is comprised of a combination of a plurality of focus ring pieces formed by dividing the focus ring in the circumferential direction of the annular shape, and the annular band member that urges each of the focus ring pieces toward the center of the focus ring, plasma can be prevented from spreading into the gap between the mounting stage and the focus ring, and as a result, damage to a side wall of the mounting stage and attachment of particles to the substrate to be processed can be prevented, thus enabling accurate plasma processing to be carried out.

Accordingly, in a third aspect of the present invention, there is provided a focus ring with an annular shape that is provided in an outer peripheral edge portion of an upper surface of a mounting stage of a plasma processing apparatus having an accommodating chamber in which a substrate is accommodated and subjected to plasma processing, and the mounting stage that is disposed in the accommodating chamber and on which the substrate is mounted, comprising an upper member with an annular shape, and a lower member with an annular shape, wherein the upper member comprises a combination of a plurality of upper member pieces formed by dividing the upper member in a circumferential direction of the annular shape, and an annular band member that urges each of the upper member pieces toward a center of the upper member.

According to the third aspect of the present invention, because the focus ring is comprised of the upper member with an annular shape and the lower member with an annular shape, the upper member is divided into a plurality of parts in the circumferential direction, and the annular band member urges each of the separate upper member pieces toward the center of the upper member, an internal stress of the upper member arising from a change in the temperature thereof can be diffused to prevent damage such as cracking, and the upper member can change its inner diameter in response to expansion or contraction of the mounting stage resulting from a temperature change. As a result, the gap between the mounting stage and the upper member can be eliminated, and thus, spread of plasma and damage to the side wall of the mounting stage and attachment of particles to the substrate to be processed resulting from the spread of plasma can be prevented.

The third aspect of the present invention can provide a focus ring, wherein abutting portions of upper member pieces in the combination form joint structures that vertically overlap each other.

According to the third aspect of the present invention, because the abutting portions of upper member pieces in the combination form joint structures that vertically overlap each other, plasma moving vertically can be prevented from spreading to the interior of the upper member through the gap between the abutting portions of the upper member pieces.

The third aspect of the present invention can provide a focus ring, wherein the upper member comprises a combination of upper member pieces formed by dividing the upper member into two, three, or four in the circumferential direction of the annular shape.

According to the third aspect of the present invention, because the upper member is comprised of a combination of upper member pieces formed by dividing the upper member into two, three, or four in the circumferential direction of the annular shape, cracking and so on caused by an internal stress can be prevented without bringing about an increase in the number of components, and moreover, because the upper member pieces having the same shape can be used, productivity, the ease of assembly, and so on can be increased.

The third aspect of the present invention can provide a focus ring, wherein the annular band member is made of resin or rubber.

According to the third aspect of the present invention, because the annular band member is made of resin or rubber, an urging force toward the center of the upper member can be easily added to each upper member piece using the elasticity of the annular band member.

The third aspect of the present invention can provide a focus ring, wherein the annular band member is disposed in a trench portion or a cut portion formed in an outer peripheral portion of the upper member, and is blocked from exposure of plasma.

According to the third aspect of the present invention, because the annular band member is disposed in a trench portion or a cut portion formed in the outer peripheral portion of the upper member, and is blocked from exposure of plasma, the annular band member can be prevented from becoming worn, damaged, and so on due to exposure to plasma.

The third aspect of the present invention can provide a focus ring, wherein the annular band member is an O-ring.

According to the third aspect of the present invention, because the annular band member is an O-ring, a sufficient urging force can be obtained by a simple constructional member, and the ease of assembly is increased.

Accordingly, in a fourth aspect of the present invention, there is provided a focus ring with an annular shape that is provided in an outer peripheral edge portion of an upper surface of a mounting stage of a plasma processing apparatus having an accommodating chamber in which a substrate is accommodated and subjected to plasma processing, and the mounting stage that is disposed in the accommodating chamber and on which the substrate is mounted, comprising an upper member with an annular shape, and a lower member with an annular shape, wherein the lower member comprises a combination of a plurality of lower member pieces formed by dividing the lower member in a circumferential direction of the annular shape, and an annular band member that urges each of the lower member pieces toward a center of the lower member.

According to the fourth aspect of the present invention, because the focus ring is comprised of the upper member with an annular shape and the lower member with an annular shape, the lower member is divided into a plurality of parts in the circumferential direction, and the annular band member urges each of a plurality of separate lower member pieces toward the center of the lower member, an internal stress of the lower member arising from a change in the temperature thereof can be diffused to prevent damage such as cracking, and the lower member can change its inner diameter in response to expansion or contraction of the mounting stage resulting from a temperature change. As a result, the gap between the mounting stage and the lower member can be eliminated, and thus, spread of plasma and damage to the side wall of the mounting stage and attachment of particles to the substrate to be processed resulting from the spread of plasma can be prevented.

The fourth aspect of the present invention can provide a focus ring, wherein the lower member comprises a combination of lower member pieces formed by dividing the lower member into two, three, or four in the circumferential direction of the annular shape.

According to the fourth aspect of the present invention, because the lower member constituting the focus ring is comprised of a combination of lower member pieces formed by dividing the lower member into two, three, or four in the circumferential direction of the annular shape, cracking and so on caused by an internal stress can be prevented without bringing about an increase in the number of components, and moreover, because the lower member pieces having the same shape can be used, productivity, the ease of assembly, and so on can be increased.

The fourth aspect of the present invention can provide a focus ring, wherein the annular band member is made of resin or rubber.

According to the fourth aspect of the present invention, because the annular band member is made of resin or rubber, an urging force toward the center of the lower member can be easily added to each lower member piece using the elasticity of the annular band member.

The fourth aspect of the present invention can provide a focus ring, wherein the annular band member is disposed in a trench portion or a cut portion formed in an outer peripheral portion of the lower member, and is blocked from exposure of plasma.

According to the fourth aspect of the present invention, because the annular band member is disposed in a trench portion or a cut portion formed in the outer peripheral portion of the lower member, and is blocked from exposure of plasma, the annular band member can be prevented from becoming worn, damaged, and so on due to exposure to plasma.

The fourth aspect of the present invention can provide a focus ring, wherein the annular band member is an O-ring.

According to the fourth aspect of the present invention, because the annular band member is an O-ring, a sufficient urging force can be obtained by a simple constructional member, and the ease of assembly is increased.

Accordingly, in a fifth aspect of the present invention, there is provided a plasma processing apparatus having an accommodating chamber in which a substrate is accommodated and subjected to plasma processing, and a mounting stage that is disposed in the accommodating chamber and on which the substrate is mounted, comprising a focus ring with an annular shape that is provided in an outer peripheral edge portion of an upper surface of the mounting stage, wherein the focus ring comprises an upper member with an annular shape and a lower member with an annular shape, and said upper member comprises a combination of a plurality of upper member pieces formed by dividing the upper member in a circumferential direction of the annular shape, and an annular band member that urges each of the upper member pieces toward a center of the upper member.

Accordingly, in a sixth aspect of the present invention, there is provided a plasma processing apparatus having an accommodating chamber in which a substrate is accommodated and subjected to plasma processing, and a mounting stage that is disposed in the accommodating chamber and on which the substrate is mounted, comprising a focus ring with an annular shape that is provided in an outer peripheral edge portion of an upper surface of the mounting stage, wherein the focus ring comprises an upper member with an annular shape and a lower member with an annular shape, and the lower member comprises a combination of a plurality of lower member pieces formed by dividing the lower member in a circumferential direction of the annular shape, and an annular band member that urges each of the lower member pieces toward a center of the lower member.

The features and advantages of the invention will become more apparent from the following detailed description taken in conjunction with the accompanying drawings.

### BRIEF DESCRIPTION OF THE DRAWINGS

FIG. 1 is a cross-sectional view schematically showing the construction of a plasma processing apparatus having a focus ring according to an embodiment of the present invention;

FIG. 2 is a horizontal cross-sectional view taken along an O-ring of the focus ring shown in FIG. 1;

FIG. 3 is an enlarged cross-sectional view showing the focus ring shown in FIG. 1 and its vicinity;

FIGS. 4A, 4B, and 4C are views useful in explaining examples of joint structures of focus ring pieces, in which FIG. 4A shows an example in which abutting surfaces of adjacent two separate pieces are inclined, FIG. 4B shows an example in which abutting surfaces of adjacent two separate pieces are hook-shaped, and FIG. 4C shows an example in which abutting surfaces of adjacent two separate pieces have an engaging structure;

FIG. 5 is a cross-sectional view showing a variation of the embodiment of the present invention;

FIG. 6 is an enlarged view showing a focus ring shown in FIG. 5 and its vicinity; and

FIG. 7 is a horizontal cross-sectional view showing a lower member of the focus ring shown in FIG. 5.

### DETAILED DESCRIPTION OF PREFERRED EMBODIMENTS

The present invention will now be described in detail with reference to the drawings showing a preferred embodiment thereof.

FIG. 1 is a cross-sectional view schematically showing the construction of a plasma processing apparatus having a focus ring according to an embodiment of the present invention. The plasma processing apparatus is constructed such as to carry out etching processing on a semiconductor wafer W as a substrate to be processed.

Referring to FIG. 1, the plasma processing apparatus 10 has a substantially cylindrical accommodating chamber 11 in which a semiconductor wafer W (hereinafter merely referred to as a “wafer W”) W is accommodated, and the accommodating chamber 11 has a processing space PS in an upper portion thereof. A cylindrical susceptor 12 as a mounting stage on which the wafer W is mounted is disposed in the accommodating chamber 11. A side face of an inner wall of the accommodating chamber 11 is covered with a side wall member 13, and an upper surface of the inner wall of the accommodating chamber 11 is covered with an upper wall member 14. The side wall member 13 and the upper wall member 14 are made of, for example, aluminum, and surfaces thereof facing the processing space PS are coated with, for example, yttria or alumite having a predetermined thickness. The accommodating chamber 11 is electrically grounded, and hence the potentials of the side wall member 13 and the upper wall member 14 are ground potentials. Moreover, the susceptor 12 is comprised mainly of a conductor unit 15 made of a conductive material, for example, aluminum, a side face covering member 16 that covers a side face of the conductor unit 15 and is made of a insulating material, and an enclosure member 17 that is mounted on an upper portion of the side face covering member 16 and made of quarts (Qz).

An exhaust flow path 18 that acts as a flow path through which gas in the processing space PS is exhausted out of the accommodating chamber 11 is formed by an inner side wall of the accommodating chamber 11 and the side face of the susceptor 12. An exhaust plate 19 that is a plate-shaped member having a large number of vent holes therein is disposed in the exhaust flow path 18. The exhaust plate 19 acts as a partition member that partitions the accommodating chamber 11 into the exhaust flow path 18 and an exhaust space ES that is a lower portion of the accommodating chamber 11. Moreover, the exhaust flow path 18 functions as a communicating portion that communicates the exhaust space ES and the processing space PS together. A roughing exhaust pipe 20 and a main exhaust pipe are connected and opened to the exhaust space ES. The roughing exhaust pipe 20 has a DP (dry pump) (not shown) connected thereto, and the main exhaust pipe 21 has a TMP (turbo-molecular pump) (not shown) connected thereto.

The roughing exhaust pipe 20, the main exhaust pipe 21, the DP, the TMP, and so on constitute exhaust equipment, and the roughing exhaust pipe 20 and the main exhaust pipe 21 exhausts gas in the processing space PS out of the accommodating chamber 11 via the exhaust flow path 18 and the exhaust space ES. Specifically, the roughing exhaust pipe 20 reduces the pressure in the processing space PS from atmospheric pressure down to a low vacuum state, and the main exhaust pipe 21 is operated in collaboration with the roughing exhaust pipe 20 to reduce the pressure in the processing space from atmospheric pressure down to a high vacuum state, which is at a lower pressure than the low vacuum state (e.g. a pressure of not more than 133 Pa (1 Torr)).

A first radio frequency power source 22 is connected to the conductor unit 15 of the susceptor 12 via a matcher 23, and supplies radio frequency electrical power of a relatively high frequency, for example 40 MHz. The susceptor 12 thus acts as a radio frequency electrode to apply radio frequency electrical power of 40 MHz to the processing space PS. It should be noted that the matcher 23 reduces the reflection of radio frequency electrical power from the conductor unit 15, thereby maximizing the efficiency of supply of the radio frequency electrical power to the conductor unit 15.

Also, a second radio frequency power source 24 is connected to the conductor unit 15 of the susceptor 12 via a matcher 25, and applies radio frequency electrical power of a lower frequency, for example, 2 MHz than the frequency of the radio frequency electrical power supplied by the first radio frequency power source 22 to the conductor unit 15.

An electrostatic chuck (ESC) 27 having an electrostatic electrode plate 26 therein is provided in an uppermost portion of the susceptor 12. The electrostatic chuck 27 is formed by placing an upper disk-shaped member, which has a smaller diameter than a lower disk-shaped member having a certain diameter, over the lower disk-shaped member, and a lower DC power supply 28 is electrically connected to the electrostatic electrode plate 26. When a wafer W is mounted on the susceptor 12, the wafer W is disposed on the electrostatic chuck 27. Upon a negative DC voltage being applied to the electrostatic electrode plate 26, a positive potential is produced on a rear surface of the wafer W. A potential difference thus arises between the electrostatic electrode plate 26 and the rear surface of the wafer W, and hence the wafer W is attracted to and held on the upper surface of the electrostatic chuck 27 through a Coulomb force or a Johnsen-Rahbek force due to the potential difference.

A focus ring 29 with an annular shape is mounted on a flat surface of an upper portion of the susceptor 12 such as to surround the attracted and held wafer W. The focus ring 29 is made of, for example, silicon (Si) or silica (SiO₂) . The focus ring 29 is exposed to the processing space PS and focuses plasma in the processing space PS toward a front surface of the wafer W, thus improving the efficiency of the etching processing. An annular cover ring 30 that is made of, for example, quarts and protects a side face of the focus ring 29 is disposed around the focus ring 29.

An annular coolant chamber 31 that extends, for example, in a circumferential direction of the susceptor 12 is provided inside the susceptor 12. A coolant, for example, cooling water or a Galden (registered trademark) fluid, at a low temperature is circulated through the coolant chamber 31 via a coolant piping 32 from a chiller unit (not shown) . A processing temperature of the wafer W attracted to and held on the upper surface of the susceptor 12 is controlled through the coolant.

A plurality of heat transfer gas supply holes 33 are opened to a portion of the upper surface of the susceptor 12 on which the wafer W is attracted and held (hereinafter referred to as the “attracting surface”). The heat transfer gas supply holes 33 are connected to a heat-transfer gas supply unit (not shown) via a heat transfer gas supply line 34 provided inside the susceptor 12. The heat transfer gas supply unit supplies, for example, helium (He) gas as a heat transfer gas via the heat transfer gas supply holes 33 into a gap between the attracting surface of the susceptor 12 and the rear surface of the wafer W.

A plurality of pusher pins 35 are provided in the attracting surface of the susceptor 12 as lifting pins that can be made to freely project out from the upper surface of the susceptor 12. The pusher pins 35 freely project out from the attracting surface. The pusher pins 35 are accommodated in the susceptor 12 when a wafer W is being attracted to and held on the attracting surface of the susceptor 12 so that the wafer W can be subjected to the etching processing, and are made to project out from the attracting surface of the susceptor 12 so as to lift the wafer W up when the wafer W is to be transferred out from the accommodating chamber 11 after the wafer W has been subjected to the etching processing.

A showerhead 36 is disposed in a ceiling portion of the accommodating chamber 11 such as to face the susceptor 12. The showerhead 36 has a disk-shaped cooling plate 38 that has a buffer chamber 37 formed therein and is made of an insulating material, an upper electrode plate 39 that is suspended from the cooling plate 38, and a lid member 40 that covers the cooling plate 38. The upper electrode plate 39 is a disk-shaped member that has a lower surface thereof exposed to the processing space PS and is made of a conductive material, for example, silicon. A peripheral edge portion of the upper electrode plate 39 is covered with an annular sealed ring made of an insulating material. That is, the upper electrode plate 39 is electrically insulated from the wall of the accommodating chamber 11, which is at a ground potential, by the cooling plate 38 and the sealed ring 41.

A process gas introducing pipe 43 is connected from a process gas supply unit (not shown) to the buffer chamber 37 in the cooling plate support 38. The showerhead 36 has therein a plurality of through gas holes 44 that communicate the buffer chamber 37 to the processing space PS. A process gas supplied from the process gas introducing pipe 43 into the buffer chamber 37 is supplied by the showerhead 36 into the processing space PS via the through gas holes 44.

A description will now be given of the construction of the focus ring, which is a characterizing portion of the present embodiment.

The focus ring 29 according to the present embodiment is comprised of, for example, a combination of two separate semicircular focus ring pieces formed by dividing the focus ring 29 in a circumferential direction of the annular shape, and the two focus ring pieces are urged toward a center of the focus ring 29 by an O-ring as an annular band member that is disposed along outer peripheral portions of the focus ring pieces.

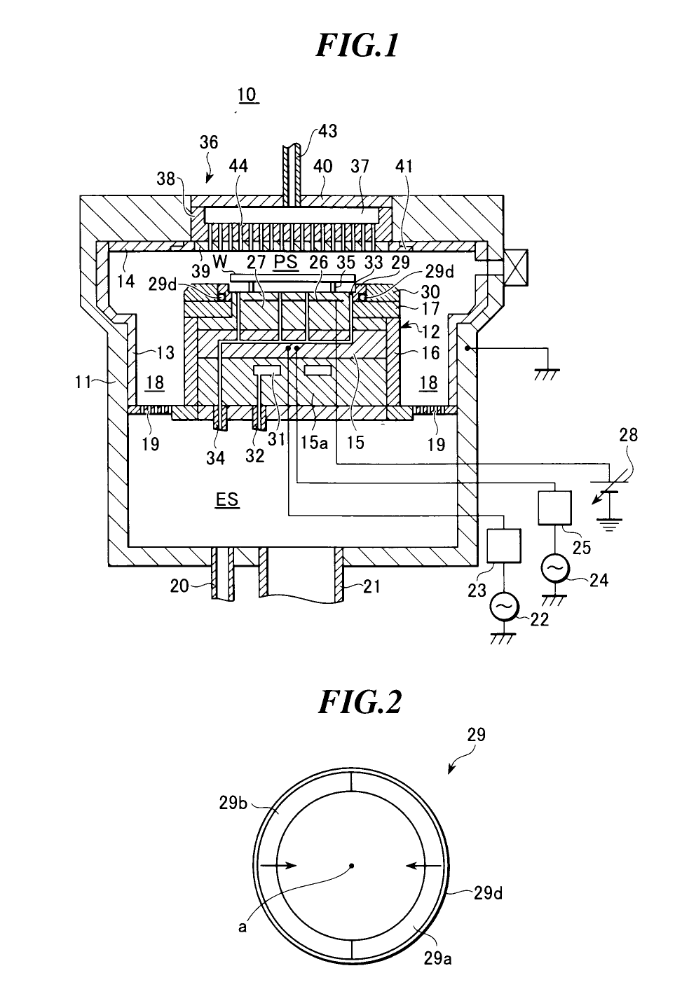

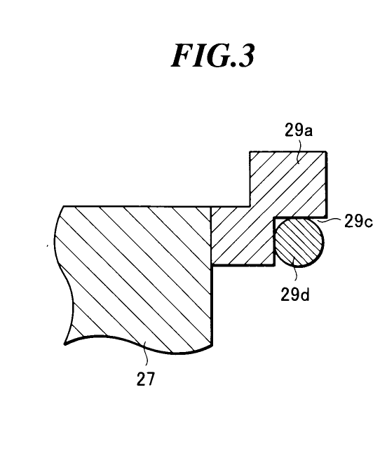

FIG. 2 is a horizontal cross-sectional view taken along an O-ring 29d of the focus ring 29 shown in FIG. 1, and FIG. 3 is an enlarged cross-sectional view showing the focus ring 29 shown in FIG. 1 and its vicinity.

Referring to FIG. 2, the focus ring 29 is divided into two right and left portions in a circumferential direction of the annular shape as viewed in the figure, and comprised of a combination of semicircular focus ring pieces 29a and 29b. The O-ring 29d as an annular band member is disposed along outer peripheral portions of the focus ring pieces 29a and 29b.

Referring to FIG. 3, an annular cut portion 29c is provided under a lower surface of the focus ring piece 29a and along an outer peripheral surface of the focus ring piece 29a. The O-ring 29d having a smaller diameter than the diameter of the cut portion 29c is engaged with the cut portion 29c. The O-ring 29d is elastic and highly resistant to radicals and is thus resistant to becoming damaged by plasma because it is made of, for example, silicon rubber. Moreover, the O-ring 29d is unlikely to generate dust. The O-ring 29d urges the focus ring pieces 29a and 29b toward a center a (see FIG. 2) of the focus ring 29. Thus, irrespective of whether the electrostatic chuck 27 as a mounting stage and the focus ring 29 change in temperature, in other words, thermally expand, inner peripheral surfaces of the focus ring pieces 29a and 29b are always in abutment with a side wall of the electrostatic chuck 27.

Specifically, in the case that the electrostatic chuck 27 is heated and thermally expands due to an increase in the internal temperature of the accommodating chamber 11, the inner diameter of the focus ring 29 comprised of the focus ring pieces 29a and 29b increases because it is pushed and widened by the side wall of the electrostatic chuck 27, and the O-ring 29d expands while holding the inner peripheral surfaces of the focus ring pieces 29a and 29b in abutment with the side wall of the electrostatic chuck 27. On the other hand, in the case that the electrostatic chuck 27 thermally contracts due to a decrease in the internal temperature of the accommodating chamber 11, the inner diameter of the focus ring 29 decreases with the contraction of the electrostatic chuck 27, and the O-ring 29d decreases in diameter while holding the inner peripheral surfaces of the focus ring pieces 29a and 29b in abutment with the side wall of the electrostatic chuck 27. Thus, the side wall of the electrostatic chuck 27 and the inner peripheral surfaces of the focus ring pieces 29a and 29b are always held in abutment with each other.

The abutting portions of the focus ring pieces 29a and 29b at both ends thereof have joint structures that vertically overlap each other.

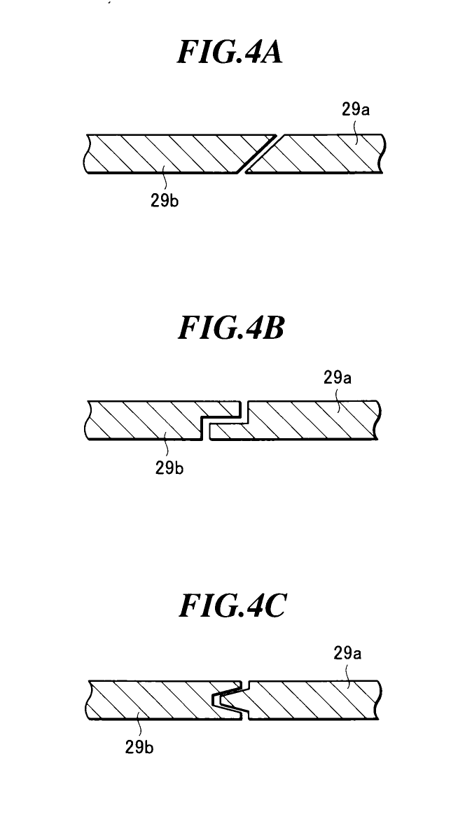

Here, the joint structures mean that ends of adjacent two separate pieces overlap each other in plan view. FIGS. 4A, 4B, and 4C are views useful in explaining examples of the joint structure of the focus ring pieces, in which FIG. 4A shows an example in which abutting surfaces of adjacent two separate pieces are inclined, FIG. 4B shows an example in which abutting surfaces of adjacent two separate pieces are hook-shaped, and FIG. 4C shows an example in which abutting surfaces of adjacent two separate pieces have an engaging structure. All of these abutting portions are constructed such that lower portions thereof are not exposed in plan view.

A description will now be given of operation of a plasma processing apparatus having the focus ring 29 constructed in the above described manner.

When reactive ion etching (RIE) processing is to be carried out on a wafer W, first, the wafer W as a substrate to be processed is mounted on the electrostatic chuck 27 as a mounting stage constructed such that the focus ring 29 is disposed on an outer peripheral edge portion of an upper surface the electrostatic chuck 27. Then, a process gas is supplied into the processing space PS via the showerhead 36, the first radio frequency power source 22 applies radio frequency electrical power of, for example, 40 MHz to the processing space PS via the susceptor 12, and the second radio frequency power source 24 applies radio frequency electrical power of, for example, 2 MHz to the susceptor 12. At this time, the process gas is excited due to the radio frequency electrical power of 40 MHz and turns into plasma. Moreover, the radio frequency electrical power of, for example, 2 MHz produces a bias voltage in the susceptor 12, and hence positive ions and electrons in the plasma are attracted to the surface of the wafer W, whereby the wafer W is subjected to the RIE processing by the positive ions and electrons.

Operation of the component parts of the plasma processing apparatus 10 described above is controlled by a CPU of a controller, not shown, provided in the plasma processing apparatus 10.

According to the plasma processing apparatus of the present embodiment, the focus ring 29 is comprised of the two semicircular focus ring pieces 29a and 29b, and the O-ring 29d that urges the focus ring pieces 29a and 29b toward the center a of the focus ring 29 is deposed along the outer peripheral portions of the focus ring pieces 29a and 29b. Thus, an internal stress of the focus ring 29 arising from thermal expansion or contraction of the focus ring 29 itself is diffused, so that the focus ring 29 can be prevented from, for example, becoming cracked or damaged. Moreover, irrespective of a temperature change, the inner peripheral surfaces of the focus ring pieces 29a and 29b are held in abutment with the side wall of the electrostatic chuck 27, and hence plasma can be prevented from spreading into a gap between the focus ring 29 and the electrostatic chuck 27. Thus, damage to the side wall of the electrostatic chuck 27 and attachment of so-called deposit to the peripheral portion of the rear surface of the wafer W resulting from spread of plasma can be prevented, and as a result, the plasma processing with high accuracy can be realized.

According to the present embodiment, the O-ring 29d is engaged with the annular cut portion 29c so that the O-ring 29d can be blocked from exposure of plasma, and hence wear of the O-ring 29d during the plasma processing can be prevented, and the longevity of the O-ring 29d can be increased. A trench portion having walls facing upper and lower portions and an inner peripheral portion of the O-ring 29d may be used in place of the cut portion 29c. This also can prevent exposure of plasma to the O-ring 29d and increase its longevity

In the present embodiment, because the abutting portions of the focus ring pieces 29a and 29b have the joint structures, exposure of plasma to constructional members below the focus ring 29, for example, the enclosure member 17 shown in FIG. 1 can be prevented, and as a result, their longevities can be increased. That is, constructional members below the focus ring 29 do not have to be treated as so-called consumables. It should be noted that in this case, the focus ring 29 exposed to plasma is treated as a consumable.

In the present embodiment, although the focus ring 29 is comprised of a combination of two separate pieces, the focus ring 29 may be a combination of three or four separate pieces. This can not only prevent cracking caused by a difference in a difference in thermal expansion, but also prevent a considerable increase in the number of components and ensure the ease of assembling because the focus ring 29 can be comprised of the focus ring pieces having the same shape.

In the present embodiment, although the focus ring pieces 29a and 29b are made of, for example, silicon, it is preferred that the inner peripheral surfaces of the focus ring pieces 29a and 29b, which are surfaces being in abutment with the electrostatic chuck 27, are covered with a ceramic or carbon coating. This can prevent wear of the abutting surfaces while securing a predetermined strength. It should be noted that if ceramic is adopted as the constituent material of the focus ring pieces 29a and 29b, the above-mentioned coating is unnecessary.

Moreover, it is preferred that the side wall of the electrostatic chuck 27, which is the surface being in abutment with the focus ring pieces 29a and 29b, is covered with a carbon coating. This can prevent wear of the electrostatic chuck 27 and considerably decrease dust generation. Similarly, the abutting surfaces of the focus ring pieces 29a and 29b at both ends thereof may be covered with a carbon coating so as to prevent wear of the abutting surfaces.

In the present embodiment, although the O-ring is used as the annular band member, the annular band member is not limited to being the O-ring, but may be any member insofar as it is annular and can urge the separate pieces toward the center of the combination of the separate pieces. The annular band member is required to be elastic and resistant to radicals and unlikely to generate dust. Examples of materials that satisfy such conditions include resin and rubber. It should be noted that in the present embodiment, although the O-ring made of silicon rubber is used as the annular band member, the material of the O-ring is not limited to being silicon rubber, but may be FFKM as fluorine rubber or a Teflon (registered trademark)-coated metallic spring. Moreover, the annular band member urges the focus ring pieces 29a and 29b toward the center a of the focus ring 29, and is not required to have a sealing function.

In the present embodiment, the focus ring is assembled by, for example, arranging the separate focus ring pieces 29a and 29b on assembling portions of the focus ring 29 to form the focus ring 29 that is annular in plan view, and then engaging the O-ring 29d as the annular band member with the cut portion 29c.

It should be noted that in the present embodiment, the focus ring 29 is provided with a notch for positioning, not shown. When the wafer W is to be mounted on the electrostatic chuck 27 after the focus ring 29 is incorporated into the plasma processing apparatus 10, the wafer W is mounted on the electrostatic chuck 27 such that a similar notch provided in the wafer W engages with the notch of the focus ring 29.

Next, a description will be given of a variation of the embodiment of the present invention.

FIG. 5 is a cross-sectional view showing the variation of the embodiment of the present invention. Referring to FIG. 5, a plasma processing apparatus 50 is basically the same as the plasma processing apparatus 10 shown in FIG. 1 in terms of construction. Specifically, the plasma processing apparatus 50 has an accommodating chamber 51 in which a substrate to be processed, not shown, is accommodated and subjected to plasma processing, a susceptor 52 that is provided in the accommodating chamber 51, an electrostatic chuck 53 that is disposed on an upper portion of the susceptor 52 and on which the substrate to be processed is mounted, and an upper electrode 54 that is provided in a ceiling portion of the accommodating chamber 51 such as to face the electrostatic chuck 53. A focus ring 55 with an annular shape is disposed in a peripheral edge portion of a flat surface of an upper portion of the electrostatic chuck 53 such as to surround a wafer W as the substrate to be processed, not shown.

The plasma processing apparatus 50 differs from the plasma processing apparatus 10 shown in FIG. 1 in that the focus ring 55 is comprised of an upper member 55a and a lower member 55b. A description will now be given of the variation with a particular emphasis on the difference from the above described embodiment.

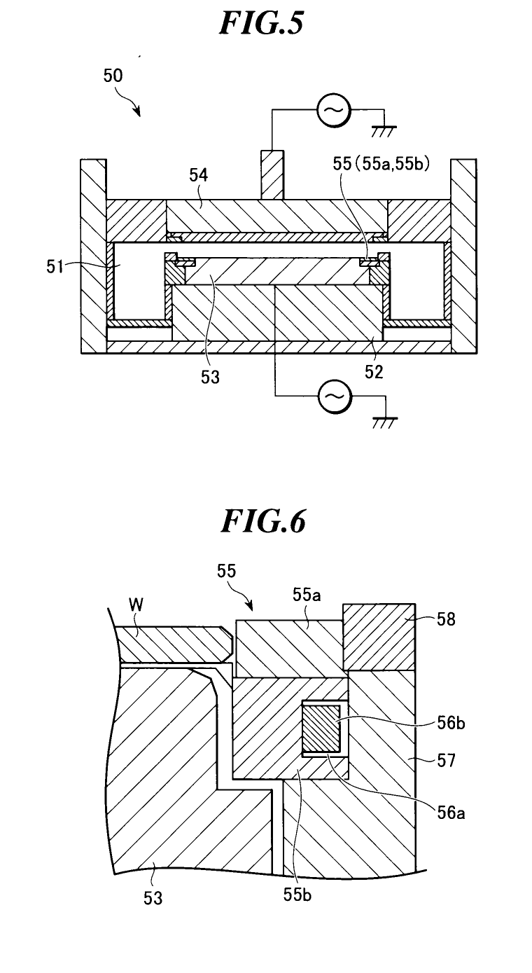

FIG. 6 is an enlarged view showing the focus ring 55 shown in FIG. 5 and its vicinity.

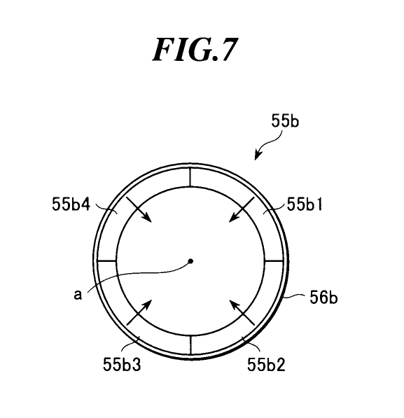

Referring to FIG. 6, the focus ring 55 is comprised of the upper member 55a and the lower member 55b. For example, as shown in FIG. 7, the lower member 55b is comprised of a combination of plurality of, for example, four separate lower member pieces formed by dividing the lower member 55b into four in a circumferential direction of the annular shape.

FIG. 7 is a horizontal cross-sectional view showing the lower member 55b of the focus ring 55 shown in FIG. 5. Referring to FIG. 7, the lower member 55b is comprised of lower member pieces 55b1, 55b2, 55b3, and 55b4 formed by dividing the lower member 55b in equal four parts in a circumferential direction thereof.

Referring to FIG. 6, a trench portion 56a for an annular band member is formed on a surface of the lower member 55b opposite to a surface facing the electrostatic chuck 53, and an O-ring 56b as the annular band member is engaged with the trench portion 56a. The O-ring 56b urges the lower member pieces 55b1, 55b2, 55b3, and 55b4 toward a center a of the lower member 55b (see FIG. 7), whereby an inner peripheral surface of the lower member 55b of the focus ring 55 is brought into abutment with a side wall of the electrostatic chuck 53.

According to the present embodiment, because the lower member 55b of the focus ring 55 is comprised of the four separate pieces, and the O-ring 56b as the annular band member is disposed on an outer peripheral portion of the lower member 55b, the lower member 55b never becomes broken or damaged because an internal stress of the lower member 55b is diffused even if the lower member 55b itself expands or contracts with an increase in the temperature thereof. Also, the lower member 55b can change its inner diameter in response to deformation of the electrostatic chuck 53 resulting from thermal expansion or contraction thereof, and hence the inner peripheral surface of the lower member 55b is always held in abutment with the side wall of the electrostatic chuck 53, so that no gap is formed therebetween. Thus, plasma can be prevented from spreading between the electrostatic chuck 53 and the lower member 55b, and wear of the side wall of the electrostatic chuck 53 and attachment of so-called deposit to a lower surface of the wafer W can be effectively prevented.

In the present embodiment, plasma is blocked by the upper member 55a of the focus ring 55 comprised of the upper member 55a and the lower member 55b, and hence the lower member 55b is never exposed to plasma. For this reason, abutting portions of ends of the lower member pieces of the lower member 55b should not necessarily have joint structures.

In the focus ring 55 comprised of the upper member 55a and the lower member 55b according to the present embodiment, the upper member 55a may be divided into two, three, or four instead of dividing the lower member 55b.

In this case, it is preferred that abutting portions of upper member pieces constituting the upper member 55a having the divided structure have joint structures illustrated in FIGS. 4A, 4B, and 4C referred to above. With this arrangement, plasma can be reliably blocked by the upper member 55a and thus does not reach the lower member 55b during the plasma processing, and therefore, exposure of plasma to the lower member 55b can be prevented, and the lower member 55b is exempt from being treated as a so-called consumable. Thus, the lower member 55b may be made of, for example, silicon.

In the focus ring 55 whose upper member 55a has the divided structure, silicon or ceramic is preferably adopted as the material of the upper member 55a. In the case that silicon is adopted as the material of the upper member 55a, it is preferred that a friction coefficient reducing film such as a carbon coating or a ceramic coating is formed on each of the abutting portions of ends of the upper member pieces of the divided structure. On the other hand, in the case that ceramic is adopted as the material of the upper member 55a, there is no need to form a friction coefficient reducing film such as a carbon coating. This is because ceramic itself can make a friction coefficient reducing effect in itself.

Moreover, in the case that the upper member 55a has the divided structure, and ceramic is adopted as the material of the lower member 55b, the abutting portions of the separate pieces constituting the upper member 55a should not necessarily have joint structures. This is because ceramic is more resistant to plasma than silicon or quartz, and hence even if plasma spreads into gaps between the separate pieces constituting the upper member 55a having the divided structure, the lower member 55b made of ceramic hardly wears.

What is claimed is:

1. A focus ring with an annular shape that is provided in an outer peripheral edge portion of an upper surface of a mounting stage of a plasma processing apparatus having an accommodating chamber in which a substrate is accommodated and subjected to plasma processing, and the mounting stage that is disposed in the accommodating chamber and on which the substrate is mounted, comprising:
a combination of a plurality of focus ring pieces formed by dividing the focus ring in a circumferential direction of the annular shape; and
an annular band member that urges each of said focus ring pieces toward a center of the focus ring.

2. A focus ring as claimed in claim 1, wherein abutting portions of focus ring pieces in said combination form joint structures that vertically overlap each other.

3. A focus ring as claimed in claim 1, wherein the focus ring comprises a combination of focus ring pieces formed by dividing the focus ring into two, three, or four in the circumferential direction of the annular shape.

4. A focus ring as claimed in claim 1, wherein said annular band member is made of resin or rubber.

5. A focus ring as claimed in claim 4, wherein said annular band member is disposed in a trench portion or a cut portion formed in an outer peripheral portion of the focus ring, and is blocked from exposure of plasma.

6. A focus ring as claimed in claim 4, wherein said annular band member is an O-ring.

7. A plasma processing apparatus having an accommodating chamber in which a substrate is accommodated and subjected to plasma processing, and a mounting stage that is disposed in the accommodating chamber and on which the substrate is mounted, comprising:
a focus ring with an annular shape that is provided in an outer peripheral edge portion of an upper surface of the mounting stage,
wherein the focus ring comprises a combination of a plurality of focus ring pieces formed by dividing the focus ring in a circumferential direction of the annular shape, and an annular band member that urges each of the focus ring pieces toward a center of the focus ring.

8. A focus ring with an annular shape that is provided in an outer peripheral edge portion of an upper surface of a mounting stage of a plasma processing apparatus having an accommodating chamber in which a substrate is accommodated and subjected to plasma processing, and the mounting stage that is disposed in the accommodating chamber and on which the substrate is mounted, comprising:
an upper member with an annular shape; and
a lower member with an annular shape,
wherein said upper member comprises a combination of a plurality of upper member pieces formed by dividing said upper member in a circumferential direction of the annular shape, and an annular band member that urges each of said upper member pieces toward a center of said upper member.

9. A focus ring as claimed in claim 8, wherein abutting portions of upper member pieces in said combination form joint structures that vertically overlap each other.

10. A focus ring as claimed in claim 8, wherein said upper member comprises a combination of upper member pieces formed by dividing said upper member into two, three, or four in the circumferential direction of the annular shape.

11. A focus ring as claimed in claim 8, wherein said annular band member is made of resin or rubber.

12. A focus ring as claimed in claim 11, wherein said annular band member is disposed in a trench portion or a cut portion formed in an outer peripheral portion of said upper member, and is blocked from exposure of plasma.

13. A focus ring as claimed in claim 11, wherein said annular band member is an O-ring.

14. A focus ring with an annular shape that is provided in an outer peripheral edge portion of an upper surface of a mounting stage of a plasma processing apparatus having an accommodating chamber in which a substrate is accommodated and subjected to plasma processing, and the mounting stage that is disposed in the accommodating chamber and on which the substrate is mounted, comprising:
an upper member with an annular shape; and
a lower member with an annular shape,
wherein said lower member comprises a combination of a plurality of lower member pieces formed by dividing said lower member in a circumferential direction of the annular shape, and an annular band member that urges each of said lower member pieces toward a center of said lower member.

15. A focus ring as claimed in claim 14, wherein said lower member comprises a combination of lower member pieces formed by dividing said lower member into two, three, or four in the circumferential direction of the annular shape.

16. A focus ring as claimed in claim 14, wherein said annular band member is made of resin or rubber.

17. A focus ring as claimed in claim 16, wherein said annular band member is disposed in a trench portion or a cut portion formed in an outer peripheral portion of said lower member, and is blocked from exposure of plasma.

18. A focus ring as claimed in claim 16, wherein said annular band member is an O-ring.

19. A plasma processing apparatus having an accommodating chamber in which a substrate is accommodated and subjected to plasma processing, and a mounting stage that is disposed in the accommodating chamber and on which the substrate is mounted, comprising:
a focus ring with an annular shape that is provided in an outer peripheral edge portion of an upper surface of the mounting stage,
wherein said focus ring comprises an upper member with an annular shape and a lower member with an annular shape, and said upper member comprises a combination of a plurality of upper member pieces formed by dividing said upper member in a circumferential direction of the annular shape, and an annular band member that urges each of said upper member pieces toward a center of said upper member.

20. A plasma processing apparatus having an accommodating chamber in which a substrate is accommodated and subjected to plasma processing, and a mounting stage that is disposed in the accommodating chamber and on which the substrate is mounted, comprising:
a focus ring with an annular shape that is provided in an outer peripheral edge portion of an upper surface of the mounting stage,
wherein said focus ring comprises an upper member with an annular shape and a lower member with an annular shape, and said lower member comprises a combination of a plurality of lower member pieces formed by dividing said lower member in a circumferential direction of the annular shape, and an annular band member that urges each of said lower member pieces toward a center of said lower member.
